(19) United States
(12) Patent Application Publication
(10) Pub. No.: US 2011/0226952 A1
(43) Pub. Date: Sep. 22, 2011

(54) Reflection Sensing System

(75) Inventors: Cheng-Chung Shih, Fremont, CA (US); Yuh-Min Lin, San Ramon, CA (US); Koon-Wing Tsang, Fremont, CA (US)

(73) Assignee: Capella Microsystems, Corp., Road Town (VG)

(21) Appl. No.: 13/049,202

(22) Filed: Mar. 16, 2011

Related U.S. Application Data
(60) Provisional application No. 61/315,401, filed on Mar. 19, 2010.

(51) Int. Cl. G01J 5/10; H01L 31/147; G01J 1/42

(52) U.S. Cl. 250/338.1; 250/552; 250/336.1

(57) ABSTRACT

A reflection sensing system comprises a body, an illuming module and a detecting module. The body is made by low temperature co-fired ceramic (LTCC) technology or other plasticity colloids and disposed a plurality of electronic connecting points. The illuming module includes a first accommodating space and a light emitted diode (LED), and the detecting module includes a light detector. The first accommodating space is disposed on the body and having a first open at one side. The cross-section of the first accommodating space is parabolic. The LED is disposed at the site of the focus of the first accommodating space, connected to the electronic connecting points and facing to the first open. The light detector is disposed on the body, connected to the electronic connecting points and providing sensing signals after receiving light.

### BACKGROUND OF THE INVENTION

1. Field of the Invention

The present invention relates to a reflection sensing system, and more particularly to a reflection sensing system having a casing made of low temperature co-fired ceramic technique or other plasticity colloids so as to have light concentrating efficacy.

2. Description of the Related Art

At the present time, a photosensor used in a proximity sensor receives light beam, which is reflected by an object, directly scattered from a light emitting diode to correspondingly generate a sensing signal. However, since a conventional light emitting diode directly emits light for each direction, light beam that is at right ahead is obviously insufficient. When an object approaches the proximity sensor, the reflected light sensed by the photosensor may not be good enough to frequently cause situations of reaction insensitivity or error detection. When the proximity sensor must be placed in rear of casings such as a light transmissive glass or a light transmissive acrylic, the clutter of surfaces of the transparent glass or acrylic casings may cause difficulty in mass productions. Therefore, it is an important issue to enhance the light beam irradiation which is right ahead of the proximity sensor and to reduce the interference from the transparent casing such that the photosensor can effectively sense light reflected by the object.

### SUMMARY OF THE INVENTION

In view of the shortcomings of the prior art, the inventor(s) of the present invention based on years of experience in the related industry to conduct extensive researches and experiments, and finally developed a reflection sensing system as a principle objective so that problems of insensitivity or error detection caused by insufficient incident light which is received by a photosensor of the reflection sensing system can be overcome.

To achieve the foregoing objective, the reflection sensing system of the invention comprises a main body, a light emitting module and a sensing module. The main body is made of a low temperature co-fired ceramic technique or other plasticity colloids. The main body is equipped with a plurality of electric junctions. The light emitting module comprises a first containing space and the light emitting diode. The sensing module comprises a photosensor. The first containing space is disposed to the main body, and one end of the first containing space has a first opening. The cross-section of the first containing space is or can be similar to a parabola. The light emitting diode is disposed in the first containing space and electrically connected to the electric junctions, and the light emitting diode is disposed near a focus of the parabola cross-section of the first containing space and faces the first opening. The photosensor of the sensing module is disposed on the main body and electrically connected to the electric junctions to correspondingly provide sensing signals after receiving light beams.

The sensing module further comprises a second containing space. The second containing space surrounds the photosensor to be disposed on the main body, and one end of the second containing space has a second opening.

The reflection sensing system further comprises a cover body. The cover body has a first hole and a second hole. The first hole corresponds to the first opening, and the second hole corresponds to the second opening.

The cover body is composed of a light insulation material. The light insulation material comprises a low temperature co-fired ceramic material, a light tight plastic and a metal material.

The first containing space, the second containing space or an inner surface of the first containing space can reflect light or be coated with a reflection material for reflecting light.

The reflection material may comprise silver, gold or aluminum.

The reflection material may further comprise silver coating, gold coating or aluminum coating.

An included angle of 20 to 80 degrees is between a tangent of a wall surface of the first containing space and a bottom of the main body.

An included angle of 40 to 60 degrees is between a tangent of a wall surface of the first containing space and a bottom of the main body.

The light emitting diode can emit invisible light.

The light emitting diode can emit infrared light.

The reflection sensing system of the invention has one or more advantages as the following:

(1) By disposing the light emitting diode at a focus inside the first containing space in which a cross-section is parabola, the reflection sensing system can enhance the light quantity irradiating objects such that the light quantity reflected by the object can be increased and easily detected so as to overcome the insensitivity or error detection of the photosensor.

(2) The reflection sensing system can eliminate side light emitted by the light emitting diode by the aperture design of the first hole of the dual-hole upper cover. The side scattering interference light passing through the transparent glass or the acrylic casing from the light emitting diode can be greatly reduced through the position of the second hole of the dual-hole upper cover and the relative position between the aperture and the photosensor.

(3) The reflection sensing system can be applied to paper color detection through different light sources and sensors such as a combination of a white light emitting diode and a RGB sensor.

### BRIEF DESCRIPTION OF THE DRAWINGS

FIG. 1 is a schematic diagram of a reflection sensing system according to an embodiment of the present invention;

FIG. 2 is a schematic diagram of a light emitting module of a reflection sensing system according to the present invention;

FIG. 3 is a schematic diagram of a sensing module of a reflection sensing system according to the present invention; and

FIG. 4 is a schematic diagram of a reflection sensing system according to an embodiment of the present invention.

### DETAILED DESCRIPTION OF THE PREFERRED EMBODIMENTS

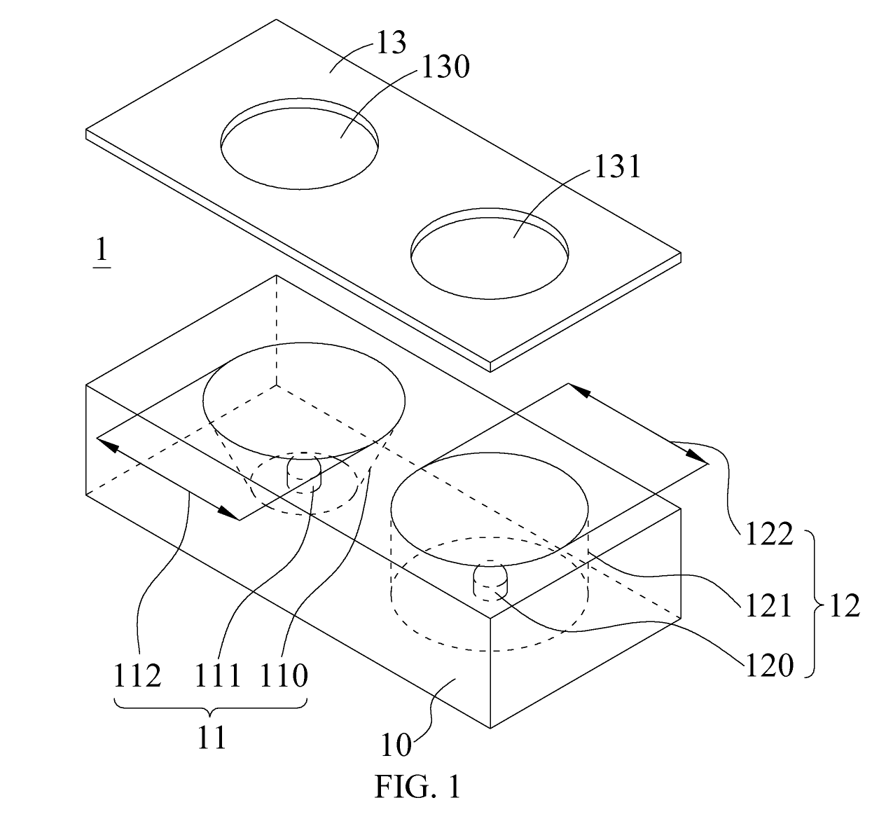

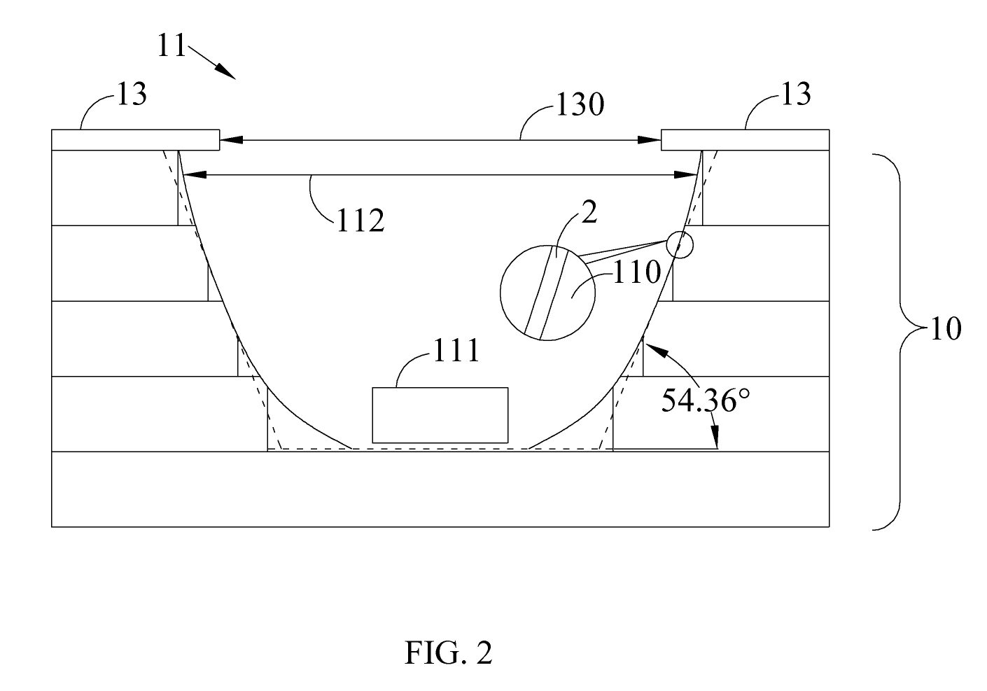

With reference to FIG. 1 for a schematic diagram of a reflection sensing system in accordance with the present invention is depicted. The reflection sensing system 1 of the invention comprises a main body 10, a light emitting module 11 and a sensing module 12, wherein the main body 10 is made of low temperature co-fired ceramic technique or other plasticity colloid. The main body 10 is equipped with a plurality of eclectic junctions (not shown in the figure). The light emitting module 11 comprises a first containing space 110 and a light emitting diode 111. The sensing module 12 comprises a photosensor 120. The first containing space 110 is disposed to the main body 10, and one end of the first containing space 110 has a first opening 112. The cross-section of the first containing space 110 can be a straight line that is similar to parabola or preferably similar to parabola (as shown in FIG. 2). Low temperature co-fired ceramic technique is that while stacking a multilayered raw embryo, the arrangement of raw embryo of each layer is simultaneously regulated to further fine-adjust the inclination and smoothness of a wall surface of the first containing space 110. Afterward the process of low temperature sintering is performed. Accordingly, the preparation of the first containing space 110, in which the cross-section has parabola, can be finished under a condition of not harming the main body 10. In addition, the light emitting diode 111 is disposed in the first containing space 110 and electrically connected to the electric junctions, and the light emitting diode 111 is disposed at a focus of cross-section parabola of the first containing space 110 and faces the first opening 112 (as shown in FIG. 2).

In addition, the photosensor 120 of the sensing module 12 is disposed to the main body 10 and electrically connected to the electric junctions to correspondingly generate a sensing signal after receiving light beam. The photosensor 120 is disposed to the same main body 10 together with the light emitting module 11. The sensing module 12 further comprises a second containing space 121. The second containing space 121 surrounds the photosensor 120 to be disposed on the main body 10. One end of the second containing space 121 has a second opening 122. The photosensor 120 is placed in the second containing space 121 and faces the second opening 122. Since the electric junctions are connected, the light emitting diode 111 and the photosensor 120 can be connected to each other, transmit signals to outside or be controlled by outside.

Moreover, the reflection sensing system 1 further comprises a cover body 13. The cover body 13 has a first hole 130 and a second hole 131. The first hole 130 corresponds to the first opening 112. The second hole 131 corresponds to the second opening 122. The cover body 13 is composed of a light insulation material. The light insulation material comprises low temperature co-fired ceramic material, light tight plastic and metal material. With the light insulation performed by the cover body 13, the photosnesor 120 can be prevented from being influenced by the light emitting diode 111.

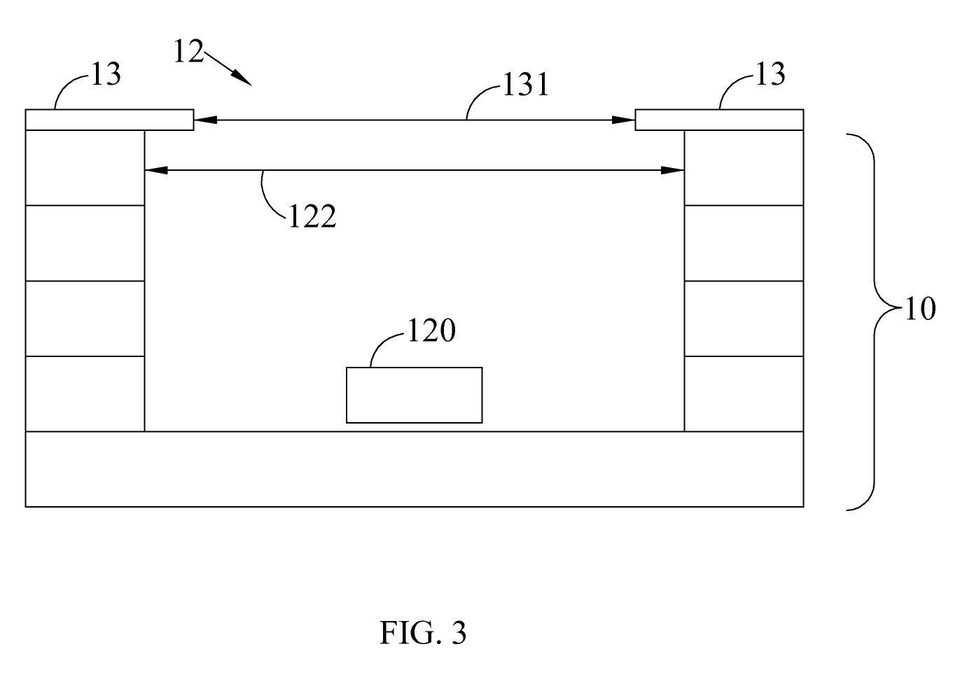

As shown in FIG. 2, the first containing space 110, the second containing space 121 or an inner surface of the first containing space 110 can directly reflect light or be coated with a reflection material 2 for reflecting light. In some preferred embodiments, the reflection material 2 can be silver, gold, aluminum, silver coating, gold coating or aluminum coating. In addition, an included angel of 20 to 80 degrees is preferably between a bottom of the main body 10 and the tangent of a wall surface of the first containing space 110. Moreover, an included angle of 40 to 60 degrees is better, and an included angle of 54.36 degrees is the best. In addition, please refer to FIG. 3. FIG. 3 is a schematic diagram of a sensing module of a reflection sensing system according to the present invention.

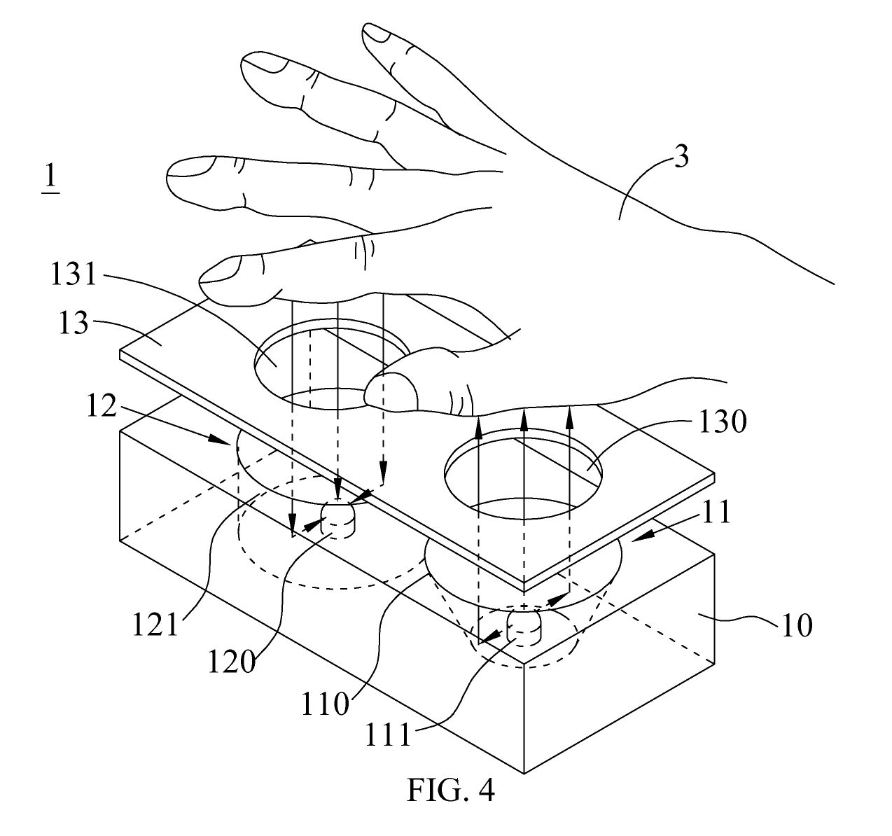

With reference to FIG. 4 for a schematic diagram of a reflection sensing system in accordance with an embodiment of the invention is depicted. In the embodiment, the light emitting diode 111 emits invisible light or preferably emits infrared light. As shown in the figure, light emitted by the light emitting diode 111 placed on an internal focus of the first containing space 110 then is instantly radiated in parallel after collecting light beam from each direction through its parabolic cross-section. When the object 3 approaches the reflection sensing system 1, the parallel radiated light beam is reflected to the sensing module 12. The sensing module 12 collects the reflected light beam into the photosensor 120 through the second containing space 121. The photosensor 120 correspondingly generates the sensing signals based upon the sensed light beam and transmits the sensing signals through the electric junctions electrically connected.

In addition, in other preferred embodiments, the reflection sensing system 1 can be applied to paper color detection through different light emitting diodes 111 and the photosensors 120 such as a combination of white light emitting diodes and a RGB sensor.

By disposing the light emitting diode at a focus inside the first containing space, in which the cross-section is parabola, the reflection sensing system of the invention can enhance the light quantity irradiating the object such that the light quantity reflected by the object can be easily detected, and since the photosensor is disposed in the second containing space, the light quantity sensed by the photosensor can be increased. Accordingly, the insensitivity or error detection of the photosensor can be effectively overcome. The reflection sensing system of the invention can greatly reduce the photosensor from being interfered with the side scattering interference light passing through the transparent glass or the acrylic casing from the light emitting diode by relative positions among a dual-hole upper cover, the light emitting diode and the photosensor. The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A reflection sensing system comprising:
a main body made of low temperature co-fired ceramic technique or plasticity colloids, the main body equipped with a plurality of electric junctions;
a light emitting module comprising:
a first containing space disposed to the main body, one end of the first containing space having a first opening, a cross-section of the first containing space being or being similar to a parabola; and
a light emitting diode disposed in the first containing space and electrically connected to the plurality of electric junctions, the light emitting diode placed near a focus of a parabola cross-section of the first containing space and facing the first opening; and
a sensing module comprising a photosensor disposed on the main body and connected to the plurality of electric junctions and correspondingly providing a sensing signal after receiving light.

2. The reflection sensing system as recited in claim 1, wherein the sensing module further comprises a second containing space, and the second containing space surrounds the photosensor to be disposed on the main body, and one end of the second containing space has a second opening.

3. The reflection sensing system as recited in claim 2, further comprising a cover body, wherein the cover body has a first hole and a second hole, and the first hole corresponds to the first opening, and the second hole corresponds to the second opening.

4. The reflection sensing system as recited in claim 3, wherein the cover body comprises a light insulation material, and the light insulation material comprises a low temperature co-fired ceramic material, a light tight plastic and a metal material.

5. The reflection sensing system as recited in claim 2, wherein the first containing space, the second containing space or an inner surface of the first containing space reflect light or are coated with a reflecting material for reflecting light.

6. The reflection sensing system as recited in claim 5, wherein the reflecting material comprises silver, gold or aluminum.

7. The reflection sensing system as recited in claim 5, wherein the reflecting material comprises silver coating, gold coating or aluminum coating.

8. The reflection sensing system as recited in claim 2, wherein an included angle of 20 to 80 degrees is between a tangent of a wall surface of the first containing space and a bottom of the main body.

9. The reflection sensing system as recited in claim 8, wherein an included angle of 40 to 60 degrees is between a tangent of a wall surface of the first containing space and a bottom of the main body.

10. The reflection sensing system as recited in claim 1, wherein the light emitting diode emits invisible light.

11. The reflection sensing system as recited in claim 10, wherein the light emitting diode emits infrared light.
